(19) United States
(12) Patent Application Publication
(10) Pub. No.: US 2012/0236529 A1
(43) Pub. Date: Sep. 20, 2012

(54) Method And Apparatus For A Light Source

(75) Inventors: Chin Ewe Phang, Penang (MY); Meng Ee Lee, Penang (MY); Eng Chuan Ong, Penang (MY)

(73) Assignee: Avago Technologies ECBU IP(Singapore) Pte. Ltd., Fort Collins, CO (US)

(21) Appl. No.: 13/363,926

(22) Filed: Feb. 1, 2012

Related U.S. Application Data
(63) Continuation-in-part of application No. 13/048,136, filed on Mar. 15, 2011.

(51) Int. Cl. G03B 15/02; H01L 33/54; F21V 9/16; H01L 33/50

(52) U.S. Cl. 362/16; 257/98; 438/27; 362/84; 257/E33.061; 257/E33.059

(57) ABSTRACT

A light-emitting device and method for manufacturing the device are disclosed. In one embodiment, an optical coupling layer can formed on a substrate encapsulating a light source die. An encapsulation layer can be formed on the optical coupling layer. A top portion of the encapsulation layer can be flat and the encapsulation can comprise a high density layer and a low density layer. The high density layer can comprise wavelength-converting material precipitated on one side of the encapsulation layer. The low density layer can comprise the wavelength-converting material in particle form suspended within the encapsulation layer. In another embodiment, the method for making the light-emitting device is disclosed.

This is a continuation-in-part of U.S. application Ser. No. 13/048,136 filed on Mar. 15, 2011, which application is incorporated by reference herein.

### BACKGROUND

Light-emitting diodes (referred to hereinafter as LEDs) represent one of the most popular light-emitting devices today. Due to the small form factor and low power consumption, LEDs are widely used in electronic mobile devices as indicator lights, light sources for Liquid Crystal Displays or LCDs, as well as flashes in camera phones, digital cameras and video recording devices. Compared to Xenon flashes used in most cameras, LEDs are superior in terms of size and power consumption. For example, an LED in a flash application may have a thickness of 0.6 mm compared to Xenon flashes that has a thickness of 1.3 mm. The small form factor makes LEDs suitable in mobile camera devices or mobile phones with a camera feature that may have an overall thickness less than 5 mm. In addition, unlike Xenon flashes, LEDs do not require charging time before use.

Generally, most light-emitting devices are not made for a single application, but for multiple applications. The light-emitting devices used in flashes are usually high power and high output light sources. Therefore, other suitable applications for light-emitting devices used in flashes are high power applications, such as indicator lights, light sources used in lighting fixtures or light sources used in infotainment displays. Electronic infotainment display systems are usually large-scale display systems, which may be found in stadiums, discotheques, electronic traffic sign displays and infotainment billboards along streets and roadways. Electronic infotainment displays may be configured to display text, graphics, images or videos containing information or entertainment contents.

Most of the flashes used today are white light sources. However, light produced by light source dies in most LEDs are generally a narrow banded light having a peak wavelength ranging from ultra violet to green wavelength. The output of the light source die is then typically converted to a broad spectrum white light by means of a wavelength-converting material. One example of a wavelength-converting material is phosphor. The wavelength-converting material may absorb a portion of light, resulting in light loss. The light lost is usually not substantial, but may be significant if the wavelength-converting material is thick.

There are several design considerations in designing a light-emitting device, such as viewing angle, color point, heat dissipation, power consumption and form factor, to name a few. Generally light-emitting devices are designed giving priority to design considerations in a primary application. For example, the light-emitting devices targeted for a flash application in camera devices tend to be small in form factor and have a high light output. However, light-emitting devices can often be used outside the targeted, primary application.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements.

FIG. 1 illustrates a cross-sectional view of a light-emitting device having sidewalls;

FIG. 2 illustrates a cross-sectional view of a light-emitting device without sidewalls manufactured using a transfer mold process;

FIG. 3 illustrates a cross-sectional view of a light-emitting device having a layer of wavelength-converting material coated on the light source die;

FIG. 4A illustrates a perspective view of a light-emitting device manufactured using a group casting method;

FIG. 4B illustrates a cross-sectional view of the light-emitting device shown in FIG. 4A taken along line 4-4;

FIG. 4C illustrates density of the wavelength-converting material in the encapsulation layer of the light-emitting device shown in FIGS. 4A and 4B;

FIG. 5A illustrates a perspective view of a light-emitting device having a flip chip die manufactured using a group casting method;

FIG. 5B illustrates a cross-sectional view of the light-emitting device shown in FIG. 5A taken along line 5-5;

FIG. 6 illustrates a cross-sectional view of a light-emitting device having connector pads located away from the side;

FIGS. 7A-7H illustrate how light-emitting devices are fabricated using a group casting method;

FIG. 8 illustrates a flow chart representing a method for manufacturing a light-emitting device;

FIG. 9 illustrates a light-emitting device with a optical coupling layer;

FIG. 10 illustrates additional steps involving fabrication of the light-emitting device shown in FIG. 9;

FIG. 11 illustrates a light-emitting source package having a lead frame;

FIG. 12 illustrates a flash system;

FIG. 13 illustrates a block diagram of a mobile device; and

FIG. 14 illustrates a lighting apparatus.

### DETAILED DESCRIPTION

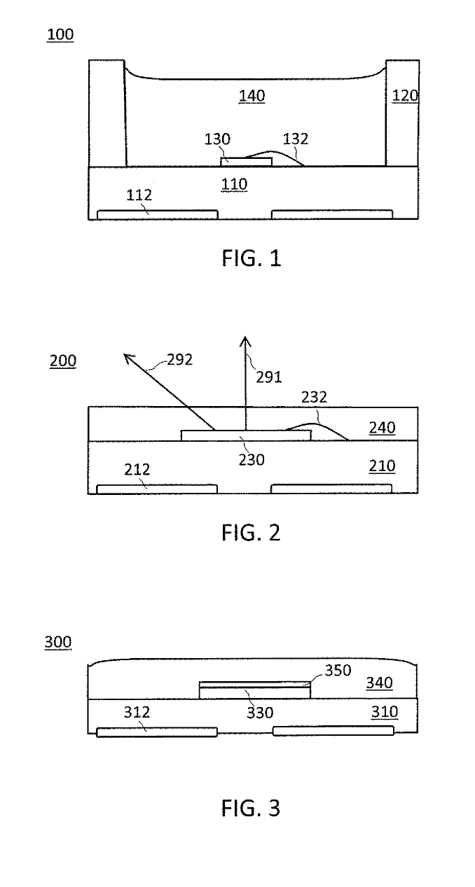

FIG. 1 illustrates a cross-sectional view of a light-emitting device 100. The light-emitting device 100 comprises a substrate 110, connector pads 112, a body 120, a light source die 130, a wire bond 132 bonding the die 130 to the substrate 110, and an encapsulant 140. The encapsulant 140 encapsulates the light source die 130 and the wire bond 132. The body 120 defines side walls configured to direct light from the light-emitting device. Due to the intermolecular forces that holds the liquid together when the encapsulant 140 is in a liquid-form during the manufacturing process, the top surface of the encapsulant 140 may not be completely flat. The body 120 may be molded. While the body 120 may increase the reliability performance, the body 120 occupies substantial space that may be otherwise reduced.

FIG. 2 illustrates a light-emitting device 200 without sidewalls manufactured by means of a transfer mold process. The light-emitting device 200 comprises a substrate 210, connector pads 212, a light source die 230, a wire bond 232 bonding the die 230 to the substrate 210, and an encapsulation layer 240. The encapsulation layer 240 may be formed from a B-stage encapsulant mixed with a wavelength-converting material (not shown). A B-stage encapsulant is an intermediate stage in the reaction of certain thermosetting resins, in which the material softens when heated, and swells when in contact with certain liquids, but the material may not entirely fuse or dissolve. The wavelength-converting material (not shown) is distributed substantially evenly in the encapsulation layer 240. The wavelength-converting-material (not shown) may cause light loss as a portion of light may be absorbed. The encapsulation layer 240 may be required to have a certain thickness, in order to enable the functionality of the encapsulation layer 240 to protect the light source die 230 from moisture and vibration. However, the light loss may become significant, as the thickness of encapsulation layer 240 is increased.

An effective way to reduce light loss is by using a thin layer of light-converting material 350, as shown in FIG. 3, which illustrates a cross-sectional view of a light-emitting device 300 comprising a substrate 310, connector pads 312, a light source die 330, a thin layer of wavelength-converting material 350 coated on the light source die 330, and an encapsulation layer 340. The encapsulation layer 340 encapsulates the light source die 330 and the thin layer of wavelength-converting material 350. The wavelength-converting material 350 may be attached to an upper relatively flat surface of the light source die 330. Therefore, the light source die 330 is usually a flip chip die. The encapsulation layer 340 may be formed using a spin molding or a spinning process. The encapsulation layer 340 may not be flat. In addition, the spin molding process may not be cost effective.

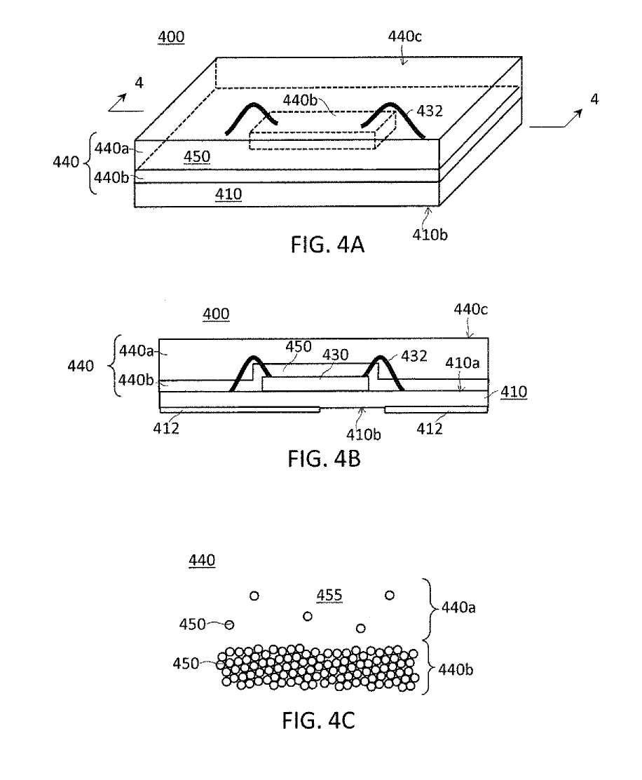

One cost effective method for manufacturing a miniature light-emitting device with minimum light loss and a flat top surface is to use a group casting method. FIG. 4A illustrates a perspective view of light-emitting device 400. FIG. 4B shows a cross-sectional view of the light-emitting device 400 along line 4-4, shown in FIG. 4A. Referring to FIGS. 4A and 4B, the light-emitting device 400 comprises a substrate 410, connector pads 412, a light source die 430, a wire bond 432 connecting the die 430 to the substrate 410, an encapsulation layer 440 encapsulating the light source die 430 and the wire bond 432, and a wavelength-converting material 450.

The substrate 410 is substantially flat with an upper surface 410a and a bottom surface 410b. The substrate 410 may be a printed circuit board (referred herein after as PCB). The bottom surface 410b may further comprise connector pads 412. The connector pads 412 may extend from one side of the substrate 410, as shown in FIG. 4B. The connector pads 412 may be connected to an external power source (not shown) for providing power to the light-emitting device 400. The connector pad 412 may be connected to a die attach pad (not shown) through one or a plurality of conducting material(s), typically referred to as a “via” (not shown), extending from the bottom surface 410b to the top surface 410a of the substrate. The “vias”, connector pads 412 and die attach pads may function as heat dissipation vehicles, dissipating heat generated by the light source die 430 to the surroundings.

The light source die 430 is configurable to emit light. For example, the light source die 430 may be a semiconductor based LED die, such as a Gallium Nitride (GaN) die, Indium Gallium Nitride (InGaN), or any other similar die configurable to produce light having a peak wavelength ranging between 300 nm and 520 nm. The light emitted by the light source die 430 is then converted into broad-spectrum white light by the wavelength-converting material 450. The wavelength-converting material 450 may be yellow phosphor, red phosphor, green phosphor, orange phosphor or any other material capable of converting a narrow banded peak-wavelength light into broad spectrum white light.

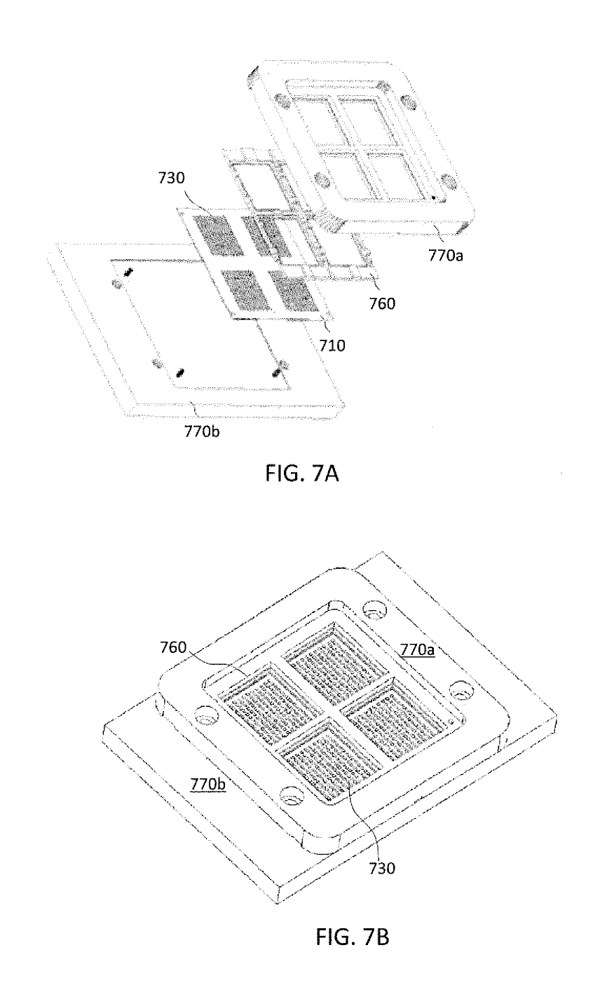

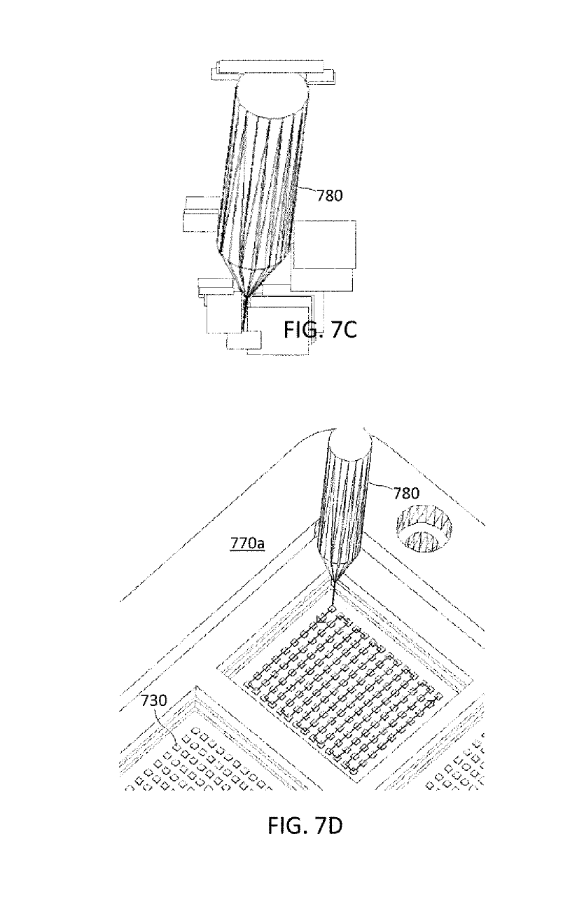

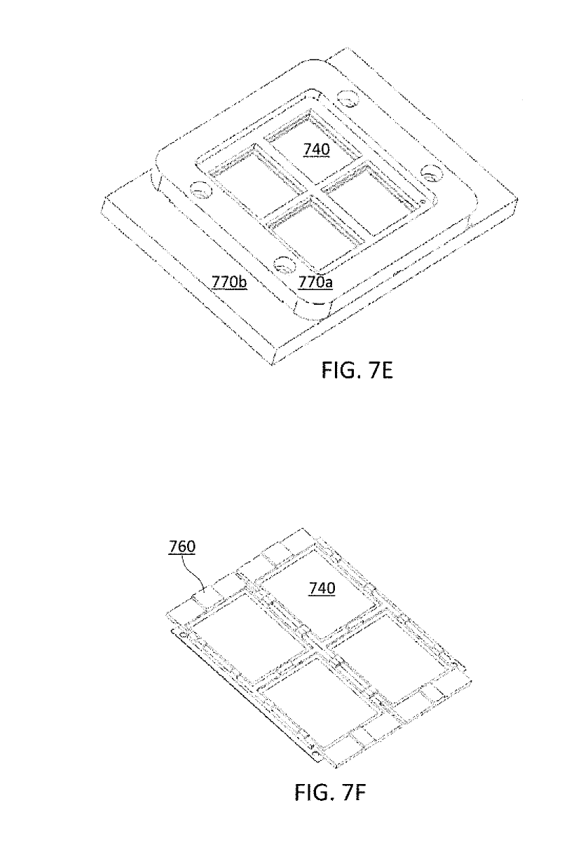

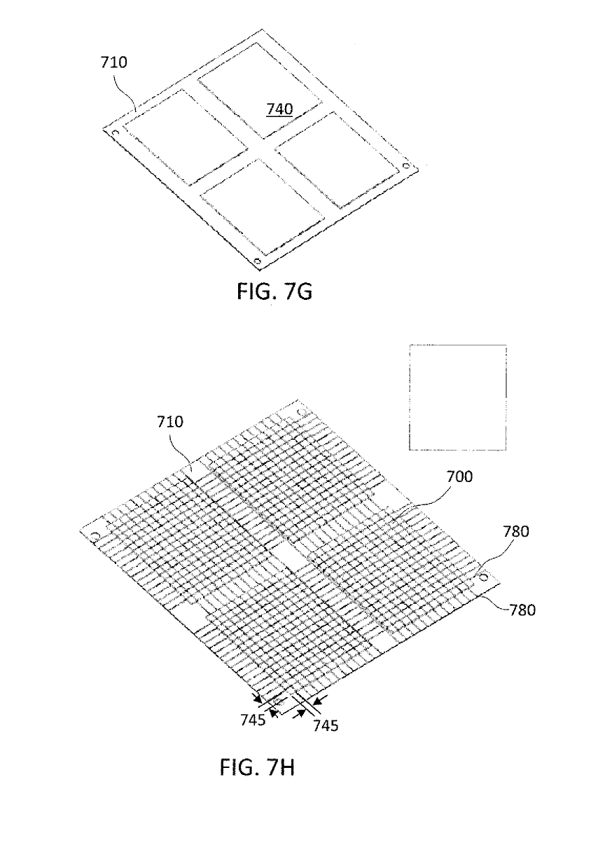

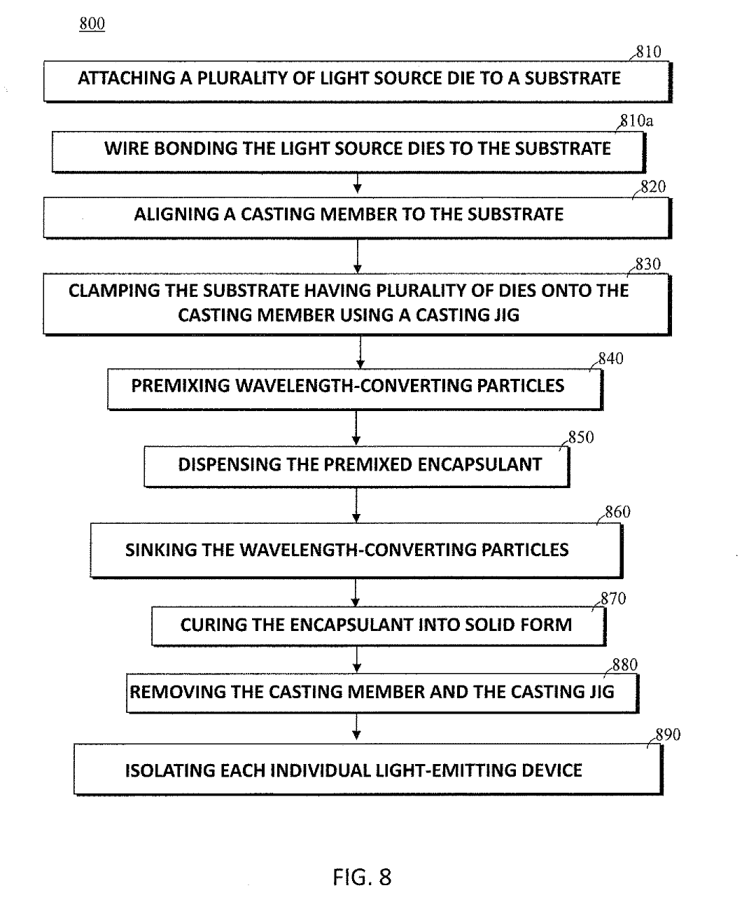

Due to manufacturing methods, the encapsulation layer 440 may further comprise a low density layer 440a and a high density layer 440b, which is further illustrated in FIG. 4C. The encapsulation layer 440 may formed by mixing wavelength-converting material 450 into an encapsulant 455 in liquid-form during the manufacturing process, and subsequently the mixture is allow to precipitate. The precipitation process may occur simultaneously during the curing process when the liquid encapsulant is cured into solid form. The encapsulant 455 may be epoxy, silicon or any other similar material. The high density layer 440b is formed by a layer of precipitated wavelength-converting material 450, as shown in FIG. 4C. The low density layer 440a, on the other hand, is not completely void of wavelength-converting material 450, but having very low density of the wavelength-converting material 450 suspended within the encapsulant 455 in particle form. The details of the manufacturing process are further discussed with reference to FIGS. 7A-7H and FIG. 8.

Unlike the light-emitting device 200, shown in FIG. 2, the encapsulant 455 used during the mixing process is in A-stage. A-stage is an early stage in the reaction of certain thermosetting resins in which the material is fusible and still soluble in certain liquids. As the encapsulant 455 is in A-stage, the wavelength-converting material 450 can be precipitated on one side. This process defines the encapsulation layer 440 into the low density layer 440a and the high density layer 440b. As the wavelength-converting material 450 is a thin layer, light loss due to the wavelength-converting material 450 is minimal. In the embodiment shown in FIG. 4B, the high density layer is in direct contact with the top surface 410a of the substrate 410. However, in other embodiments, the arrangement may be reversed such that the low density layer 440a is in direct contact with the top surface 410a of the substrate 410. The arrangement of low density layer 440a and the high density layer 440b depends on the orientation of the substrate 410 during manufacturing process as discussed further with reference to FIG. 8.

As shown in the embodiment in FIG. 4B, the wire bonds 432 are encapsulated in the encapsulation layer 440. However, a portion of the wire bond 432 is encapsulated within the high density layer 440b, while the remaining portion of the wire bond 432 is encapsulated within the low density layer 440a. In yet another embodiment, the entire wire bond 432 may be enclosed within only one of either the high density layer 440b or the low density layer 440a.

As shown in FIG. 4A, the light-emitting device 400 defines a rectangular shape. The substrate 410 and the encapsulation layer 440 are both rectangular shapes overlapping each other completely. In the embodiment shown in FIG. 4A, each of the substrate 410 and the encapsulation layer 440 have four sides respectively, which are aligned to each other, respectively. In yet another embodiment that the light-emitting device 400 may define a flat disc shape, with each of the substrate 410 and the encapsulation layer 440 having similar discs that are aligned with each other.

The top surface 440c of the encapsulation layer 440 defines a substantially flat surface without any meniscus. A meniscus is a curve in the upper surface of a standing liquid, produced in response to the surface of the container of the liquid such as the mold used to form the encapsulation layer 440. A meniscus can be either convex or concave. Due to the group casting method, discussed more fully with reference to FIG. 8 below, meniscus can be eliminated by means of a dummy area 745, as shown in FIG. 7H and discussed with reference to FIG. 8 below. This is one of the advantages of the light-emitting device 400 compared to the light-emitting device 300 shown in FIG. 3 in which the encapsulant 340 is formed individually.

Generally, both the low density layer 440a and the high density layer 440b may be substantially flat and planarly parallel to the substrate 410. However, in the embodiment shown in FIGS. 4A-4B, the high density layer 440b may not be completely flat. A portion of the high density layer 440b may be enclosing and thus defining the shape of the light source die 430. In one embodiment, the substrate 410 has a thickness of approximately 0.1 mm, the high density layer 440b has a thickness of approximately 0.25 mm and the low density layer is approximately 0.35 mm. The light source die 430 has a thickness of approximately 0.15 mm. The overall thickness of the light-emitting device 400 is approximately 0.6 mm. The dimension of the light-emitting device 400 is approximately 2.0 mm×2.0 mm×0.6 mm. Comparing the light-emitting device 400 and the light-emitting device 100 shown in FIG. 1, the light-emitting device 400 without the sidewalls 200 (See FIG. 1) can be made relatively smaller. In addition, the form factor and small size of the light-emitting device 400 is suitable for many applications, for example, flash light in mobile devices such as camera phones, compact cameras and any other camera devices, among other things.

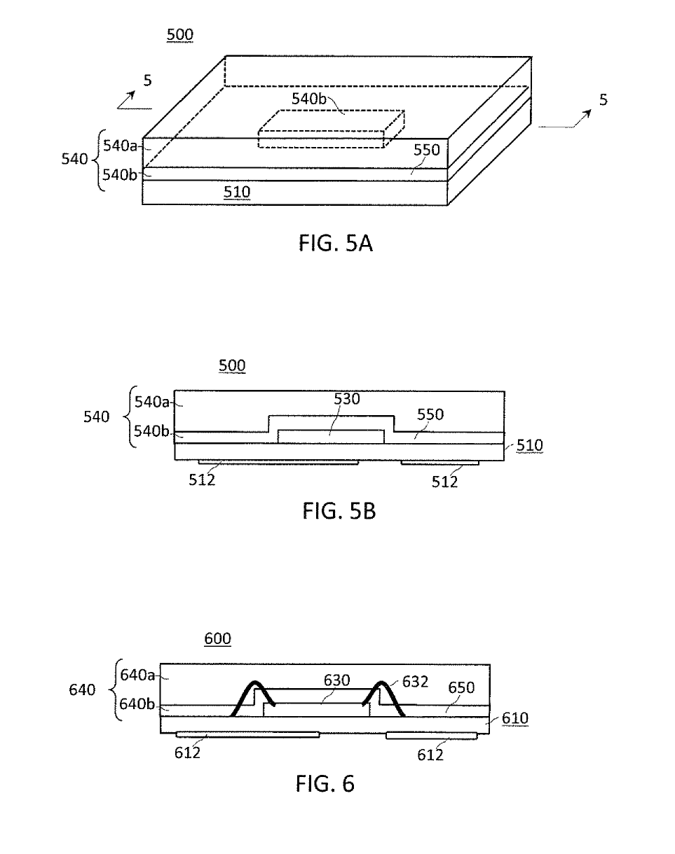

FIG. 5A illustrates a perspective view of a light-emitting device 500 having a flip chip die manufactured using a group casting method. FIG. 5B illustrates a cross-sectional view of the light-emitting device 500, shown in FIG. 5A taken along line 5-5. The light-emitting device 500 is substantially similar to the light-emitting device 400, but differs at least in the fact that the light-emitting device 500 does not have any wire bonds 432 as in FIG. 4A. The light-emitting device 500 comprises a substrate 510, connector pads 512, a light source die 530, an encapsulation layer 540 encapsulating the light source die 530, and wavelength-converting material 550. Without the wire bond 432 (in FIG. 4A), the light source die 530 is connected to the substrate 510 through solder balls (not shown), which may be used in flip chip die manufacturing. The encapsulation layer 540 of the light-emitting device 500 further comprises a high density layer 540b and a low density layer 540a, as discussed above in FIGS. 4A-4C.

FIG. 6 illustrates a light-emitting device 600, which comprises a substrate 610, connector pads 612, a light source die 630, a wire bond 632 connecting the die 630 to the substrate 610, an encapsulation layer 640 encapsulating the light source die 630 and the wire bond 632, and a wavelength-converting material 650. The encapsulation layer 640 further comprises a high density layer 640b and a low density layer 640a. The light-emitting device 600 is substantially similar to the light-emitting device 400 shown in FIG. 4B, but differs at least in the location of the connector pads 612. The connector pads 612 shown in FIG. 6 are not located at the side of the light-emitting device 600, but are located at a distance from each side of the light-emitting device 600. During some sawing processes, any metal portions, such as the connector pads 612 may be ripped off of the device during the sawing process if the metal portion is within the saw line 780 (See FIG. 7H). Thus, the separation of the metal connector pads from the sides of the device ensures the formation of the connector pads 612 without being ripped off during any sawing processes of manufacturing.

FIGS. 7A-7H illustrate how the light-emitting devices 700 are fabricated using a group casting method as discussed with reference to the flow chart of FIG. 8. Referring to FIGS. 7A-7H and FIG. 8, the method for fabricating light-emitting device 700 (shown in FIG. 7h) starts with step 810 in which a plurality of light source dies 730 are attached on a substrate 710, as shown in FIG. 7A. In the embodiment shown in FIG. 7A, the substrate 710 is a PCB having four groups of light source dies 730 (See also FIG. 7B), attached to a top surface of the substrate 710. Each group may comprise 150 light source dies 730. Alternative numbers and arrangements may be possible, depending on design and manufacturing requirements. For non-flip chip type of light source dies 730, optional step 810a may occur, in which wire bonding the light source dies 730 to the substrate 710 may be required. Next, the method proceeds to step 820 in which a casting member 760, having at least one cavity is aligned to the substrate 710, such that the light source dies 730 are enclosed within the cavity. In the embodiment shown in FIG. 7A, the casting member 760 is a casting rubber member defining four cavities configured to enclose each group of the light source dies 730. Other arrangements may be possible, including a casting member of other materials. In step 830, the casting member 760 and the substrate 710 are clamped together, using a casting jig 770a-770b, to fix the position of the casting member 760 relative to the substrate 710 as shown in FIG. 7B.

In step 840, which may be done concurrently to steps 810-830, an encapsulant having wavelength-converting material therein may be premixed. Step 840 can also be done before or after steps 810-830. The encapsulant is in A-stage that is a liquid-form. The premixed encapsulant may be placed in a dispensing apparatus 780, as shown in FIG. 7C. Generally, the encapsulant needs to be used within a predetermined time period after preparation. Therefore, although the premixing of encapsulant may be done concurrently or prior to steps 810 to 830, usually step 840 is carried out after the die attach and wire bonding are done. The encapsulant may be silicon, epoxy or any other similar material.

The method then proceeds to step 850, in which the premixed encapsulant is dispensed into or over the cavities. In the embodiment shown in FIG. 7D, the dispensing is done in a zip-zag manner. However, other dispensing patterns may be used. Next, in step 860, the wavelength-converting material is then allowed to sink or settle, such that a low density layer and a high density layer are formed. In the low density layer, the wavelength-converting material (shown in FIG. 4C) suspends within the encapsulant 740 in particle form. On the contrary, the high density layer comprises of a layer of precipitated wavelength-converting material. In the embodiment shown in FIGS. 7A-7H, the sinking or settling process is done having the top surface of the substrate 710 facing upwards. Therefore, the high density layer is formed in direct contact with the top surface of the substrate. If the sinking process is done in an opposite manner in which the top surface of the substrate 710 faces downwards, the low density layer will form in direct contact with the top surface of the substrate 710. The sinking process may be done under a condition such as the casting jig 770a-770b is rotated to ensure that the thickness of the encapsulation layer is substantially consistent. Next, the method proceeds to step 870 in which the encapsulant is cured into a solid form. Step 860 and step 870 may be done substantially simultaneously. Step 860 may also comprise other details, such as degasing the encapsulation layer. In yet another embodiment, the step 870 of curing the encapsulation layer may be done in a temperature under 150 degrees Celsius for 4 hours, which is done after step 860.

Next, the process proceeds to step 880, in which the casting member 760 and the casing jig 770a-770b are removed, as shown in FIGS. 7F-7G. Finally, the method proceeds to step 890, in which each individual light-emitting is isolated, for example by means of sawing. In the embodiment shown in FIG. 7H, the common substrate 710, having a plurality of light source dies 730 being encapsulated within a layer of encapsulation layer may be sawed. This step may also be accomplished by means of chemical or laser etching, or other known separation means. Generally, the meniscus or curvature portions are formed at the outer perimeter of the encapsulation layer, because this is where the liquid encapsulant touches the casting member 760. An area at the outer perimeter of the encapsulation layer may be selected to define a dummy area 745. Dummy area 745 is an area where the substrate 710 is without attached light source dies 730 or circuits but being enclosed by the encapsulation layer. The size of the dummy area 745 is selected such that meniscus or curvature portions are formed only within the dummy area 745. The dummy area 745 can be easily removed by sawing or other separation means. Compared to the light-emitting device 200 shown in FIG. 2 manufactured using a transfer mold method, the elimination of the dummy area 745 is cost effective. Casting the light-emitting devices 700 in groups reduce the dummy area 745 needed per unit of devices.

FIG. 7H shows saw or separation lines 780 dividing the substrate 710 into columns and rows to yield a rectangular shape light-emitting device 700. As the side of the light-emitting device is produced through sawing, the size and shape of the encapsulation layer and the substrate 710 are substantially similar. One cost effective shape for the light-emitting device 700 is rectangular shape as more devices can be fit per unit area. However, for any other customization or any needs to adapt the form factor into other shapes, the method illustrated in FIG. 8 is applicable. For example, for a disc shape device, the isolation of individual devices may be done through laser cutting, V-cutting, stamping or any other similar process instead of the sawing process illustrated in the example given above.

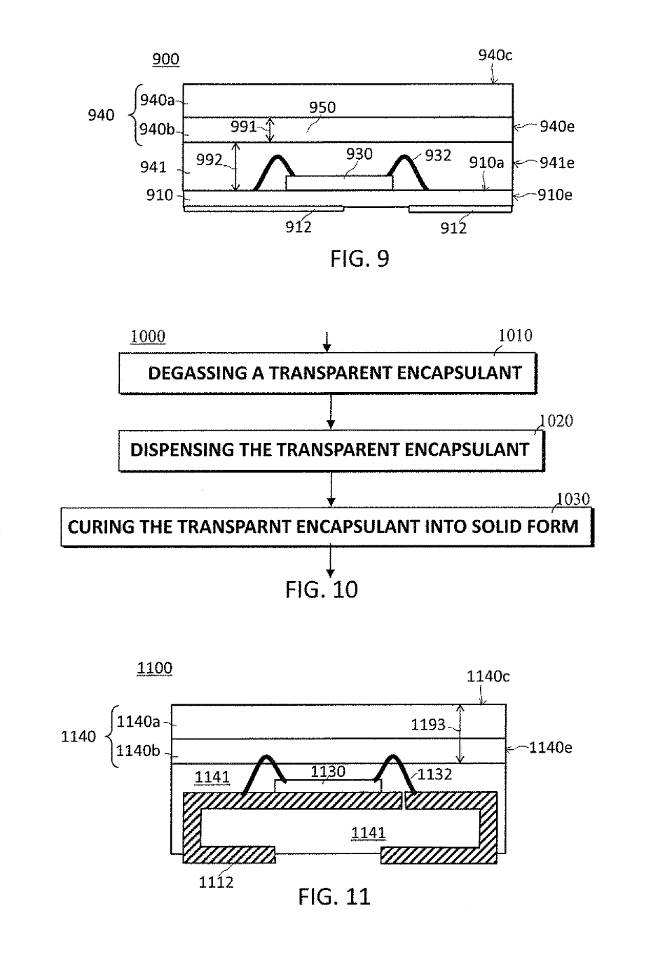

The light source die 530 (See FIG. 5) can be separated from the encapsulation layer 540 (See FIG. 5) using an additional layer as shown in various embodiments shown hereinafter. FIG. 9 illustrates an embodiment of a cross-sectional view of a light-emitting device 900 comprising a substrate 910 having a top surface 910a, connector pads 912, a light source die 930, an optical coupling layer 941 encapsulating the light source die 930, an encapsulation layer 940 formed on the optical coupling layer 941, and a wavelength-converting material 950. The substrate 910 may comprise a plurality of conductors (not shown) electrically coupled to the light source die 930. The light source die 930 is mounted on the top surface 910a of the substrate 910. Wire bonds 932 may be formed to establish electrical connection between the light source die 930 and the substrate 910. The top surface 940c of the light-emitting device 900 may be flat and may define a rectangular shape.

In the embodiment shown in FIG. 9, the optical coupling layer 941 and the encapsulation layer 940 may be formed using one single type of encapsulant. However, the optical coupling layer 941 may be formed differently than the encapsulation layer 940 by substantially avoiding addition of the wavelength converting material 950 to the optical coupling layer 941. The encapsulant may be silicone, epoxy or other similar material for encapsulating light source die 930. The encapsulant may be substantially transparent to light such that light emitted from the light source die 930 may be coupled through the optical coupling layer and the encapsulation layer without much loss.

Initially in a manufacturing process, the optical coupling layer 941 may be in liquid or semi-liquid-form to encapsulate the top surface 910a of the substrate 910 and the light source die 930, but may be cured into solid from towards an end of the process. The encapsulation layer 940 on the other hand, may be made from similar encapsulant used to form the optical coupling layer 941 but may be pre-mixed with the wavelength converting material 950 for the manufacturing process. The wavelength converting material 950 may be allowed to precipitate. This may yield a high density layer 940b and a low density layer 940a, as shown in FIG. 9. In yet another embodiment, the optical coupling layer 941 and the encapsulation layer 940 may be formed using two different types of materials, which may be two different types of epoxies.

The high density layer 940b may be formed by a layer of the wavelength-converting material 950 precipitated on one side of the encapsulation layer 940, usually in particle form, similar to the embodiment shown in FIG. 4C. The low density layer 940a may comprise a low density of the wavelength converting material 950 in particle form suspended within the encapsulant, similar to the embodiment shown in FIG. 4C. The wavelength converting material 950 may be sparsely distributed in the low density layer 940a, but may be distinguishably visible using a microscope. Accordingly, relative to the low particle density of the low density layer 940a, the high density layer 940b may have a substantially higher density of particles of the wavelength converting material 950. In contrast to the low density of particles in the low density layer 940a, the particles of the wavelength converting material 950 may be densely precipitated in the high density layer 940b. The high density layer 940b may be in direct contact with the optical coupling layer 941 as shown in FIG. 9.

However, in another embodiment, the high density layer 940b may be alternatively arranged. In another embodiment, arrangement order of the low density layer 940a and the high density layer 940b may be reversed relative to arrangement order of the low density layer 940a and the high density layer 940b as shown in FIG. 9. Accordingly, in another embodiment the low density layer 940a may be in direct contact with the optical coupling layer 941 instead.

Both the low density layer 940a and the high density layer 940b may be made substantially flat and planarly parallel to the top surface 910a of the substrate 910 as shown in FIG. 9. In embodiments that may have the optical coupling layer 941 formed below the encapsulation layer 940, the high density layer 940b may substantially avoid direct contact with the light source die 930.

Thickness 991 of the high density layer 940b may be made consistent across the entire layer. This may provide for light uniformity. Light uniformity may result because light emitted from the top surface 940c from any area may be similar in color as light propagating through substantially same thickness 991 of the wavelength converting material 950.

The wire bond 932 may be fully encapsulated as shown in FIG. 9 but alternatively a portion of the wire bond 932 may protrude into the encapsulation layer 940 such that a portion of the wire bond 932 is encapsulated by the encapsulation layer 940. In one embodiment, the wire bond 932 may protrude into the encapsulation 940 especially when the thickness 992 of the optical coupling layer 941 is less than 100 micro-meters.

Usually the light emitted from the light source die 930 may have a narrow bandwidth defining a color. The light may be coupled through the optical coupling layer 941 and may be then transformed into another color or a broad spectrum light when propagating through the wavelength converting material 950 in the encapsulation layer 940. For example, the light source die 930 may be configured to emit blue light but the light seen externally after the light going through the top surface 940c is a white color light having a broad spectrum wavelength.

Members of the light-emitting device 900 may be arranged for coupling much or most of the narrow bandwidth light emitted by the light source die 930 to the wavelength converting material 950 in the encapsulation layer 940, which may provide for efficient conversion into broad spectrum light. The high density layer 940b may directly contact edges of all sides 940e of the encapsulation layer 940e, which may define a portion of side surfaces of the entire light-emitting device. The encapsulation layer 940 and the optical coupling layer 941 may further comprise side surfaces 940e and 941e, which may have substantially similar respective perimeters with side walls that may be stacked adjacent to each other as shown in FIG. 9. Specifically, this arrangement may provide for light emitted from the light source die 930 being transmitted through the wavelength converting material 950 before exiting through the top surface 940c. For reliability considerations, the substrate 910 and the optical coupling layer 941 may further comprise side surfaces 910e and 941e, which may have substantially similar respective perimeters with side walls, and which may be stacked adjacent to each other as shown in FIG. 9.

The light-emitting device 900 may be made using the method 800 shown in FIG. 8 with additional steps 1000 shown in FIG. 10. The additional steps 1000 shown in FIG. 10 may be performed for example, between step 830 and 840 (See FIG. 8). However, the additional steps 1000 illustrated in FIG. 10 may be performed simultaneously together with step 840 shown in FIG. 8.

As shown in FIG. 10, a transparent encapsulant may be degassed in step 1010. The transparent encapsulant may then be dispensed into the cavity, so as to encapsulate the light source die and a portion of the top surface of the substrate in step 1020. In step 1030, the transparent encapsulant may then be cured into solid form, forming the optical coupling layer 941 shown in FIG. 9. Optionally, the top surface of the transparent encapsulant may be polished into a flat surface prior to dispensing of the encapsulation layer discussed in FIG. 8. The encapsulation layer may then be formed on the optical coupling layer as described in steps 840-870 shown in FIG. 8.

FIG. 11 illustrates an embodiment showing a light source package 1100. The light source package 1100 may comprise a plurality of conductors 1112, a light source die 1130 (which may be mounted on one of the conductors 1112), an optical coupling layer 1141 (which may encapsulate the light source die 1130 and a substantial portion of the conductors 1112), and a wavelength converting layer 1140 (which may be formed on the optical coupling layer 1141). Wire bonds 1132 may be formed to provide electrical connection between the light source die 1130 and the conductors 1112. The conductors 1112 may define leads electrically coupled to external circuits. As shown in the embodiment in FIG. 11, a portion of the wire bond 1132 may be encapsulated within the wavelength converting layer 1140.

In the embodiment shown in FIG. 11, the wavelength converting layer 1140 may comprise a low density layer 1140a and a high density layer 1140b. The low density layer 1140a may comprise wavelength converting particles suspended within the layer 1140a. The high density layer 1140b may comprise precipitated wavelength converting particles as shown in FIG. 4C. The low density layer 1140a of the wavelength converting layer 1140 may be identified and distinguishable from the optical coupling layer 1141 as the low density layer 1140b may comprise suspended wavelength converting particles, which may be visible at least by using a microscope. The precipitate of wavelength converting particles in the high density layer 1140b may be visible using without a microscope. The optical coupling layer 1141 may be configured to separate the wavelength converting particles in the wavelength converting layer 1140 from the light source die 1130, such that a uniform layer of precipitated wavelength converting particles can be formed in the high density layer 1140b.

The wavelength converting layer 1140 may comprise a top flat surface 1140c and at least one side surface 1140e. The top flat surface 1140c may define top surface of the light source package 1100. The at least one side surface 1140e may define a portion of side surfaces of the light source package 1100. The high density layer 1140b may be in direct contact with the optical coupling layer 1141 but in another embodiment, such arrangement can be reversed. The wavelength converting layer 1140 may have a uniform thickness 1193. The light source package 1100 may be used for packaging LEDs used in camera devices.

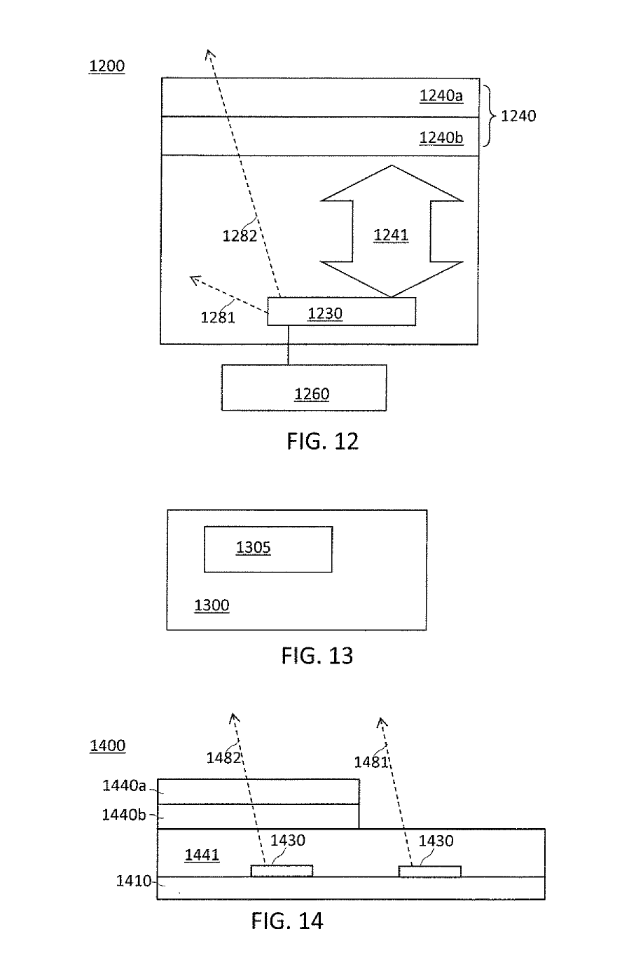

FIG. 12 illustrates an embodiment showing a block diagram of a flash system 1200. The flash system 1200 may be used in a mobile device. In particular, the flash system 1200 may be an integrated flash light source used in camera devices.

The flash system 1200 shown in the embodiment may comprise a light source 1230, a wavelength converting layer 1240, a transparent separation layer 1241, and a controller circuit 1260. The controller circuit 1260 may adapted for arrangement within the mobile device. The controller circuit may be electrically coupled with the light source 1230 for activating the light source 1230 to flash a light 1281 and 1282.

The transparent separation layer 1241 may be configured to distance the light source 1230 away from the wavelength converting layer 1240. The transparent separation layer 1241 may usually be a transparent encapsulant adaptable to transmit light. The wavelength converting layer 1240 may further comprise a low density layer 1240a having wavelength converting particles suspended within the layer, and a high density layer 1240b having precipitated wavelength converting particles as shown in FIG. 4C. The light 1281 emitted from the light source 1230 may usually comprise a narrow spectrum. Light 1282 coupled through the optical coupling layer 1141 into the wavelength converting layer 1140 may be converted into a broad spectrum light prior to exiting the flash system 1200.

FIG. 13 illustrates an embodiment showing a block diagram of a camera device 1300. The camera device 1300 may be a mobile phone, a digital camera, a camcorder, or any other similar devices having a camera function. The camera device comprises a flash 1305. The flash 1305 may be an integrated flash system 1200 shown in FIG. 12, light-emitting devices 900, or any other devices shown in various embodiments.

FIG. 14 illustrates an embodiment of a lighting apparatus 1400, which may comprise a substrate 1410, at least one light source die 1430 configured to emit light, an optical coupling layer 1441 encapsulating the at least one light source die 1430, a low density wavelength converting layer 1440a having wavelength converting particles suspended within the layer, and a high density wavelength converting layer 1440b having precipitated wavelength converting particles. In addition to flash, the lighting apparatus 1400 may comprise light fixtures used in solid-state lighting. The lighting apparatus 1400 may be configured to emit light having a different color than light emitted by light source die 1430. For example, as shown in the embodiment in FIG. 14, light 1481 emitted from the light source die 1430 may have a narrow band with a peak wavelength, and may exit the lighting apparatus 1400 via the optical coupling layer 1441. Another portion of light 1482 may exit the lighting apparatus 1400 via the wavelength converting layers 1440a and 1440b and may be converted thereby to a broad spectrum light having a different color. The broad spectrum light 1482 may be white in color whereas the narrow band light 1481 may be blue or green in color.

Although specific embodiments of the invention have been described and illustrated herein above, the invention should not be limited to any specific forms or arrangements of parts so described and illustrated. For example, the light source die described above may be an LED die or some other future light source die. Likewise, although a light-emitting device with a single die was discussed, the light-emitting device may contain any number of dies, as known or later developed without departing from the spirit of the invention. The scope of the invention is to be defined by the claims appended hereto and their equivalents. Similarly, manufacturing embodiments and the steps thereof may be altered, combined, reordered, or other such modification as is known in the art to produce the results illustrated.

What is claimed is:

1. A light-emitting device, comprising:
a substrate having a top surface;
a light source die attached to the top surface;
an optical coupling layer substantially encapsulating the light source die;
an encapsulation layer formed on the optical coupling layer, wherein the encapsulation layer further comprises a low density layer and a high density layer; and
a wavelength-converting material formed within the encapsulation layer;
wherein the wavelength converting material is suspended within the low density layer in particle form; and
wherein the wavelength-converting material precipitates on one side of encapsulation layer defining the high density layer.

2. The light-emitting device of claim 1, wherein the optical coupling layer and the encapsulation layer each further comprise respective side surfaces that have substantially similar respective perimeters with side walls that are stacked adjacent to each other.

3. The light-emitting device of claim 1, wherein the high density layer is in direct contact with all side surfaces of the light-emitting device.

4. The light-emitting device of claim 1, wherein the low density layer and the high density layer are substantially planarly parallel to the top surface of the substrate.

5. The light-emitting device of claim 1 further comprises a wire bond encapsulated within the optical coupling layer.

6. The light-emitting device of claim 5, wherein a portion of the wire bond is encapsulated within the high density layer.

7. The light-emitting device of claim 1, wherein the high density layer has a substantially uniform thickness.

8. The light-emitting device of claim 1, wherein the encapsulation layer further comprises a top flat surface defining a rectangular shape.

9. The light-emitting device of claim 1, wherein the encapsulation layer and the optical coupling layer are formed using same type of encapsulant.

10. The light-emitting device of claim 1, wherein the light-emitting device forms a portion of a camera device.

11. A method for making a plurality of light-emitting devices, the method comprising:
attaching a plurality of light source dies on a substrate;
aligning a casting member having at least one cavity to the substrate such that the light source dies are enclosed within the at least one cavity;
dispensing a transparent encapsulant into the at least one cavity encapsulating the light source die;
curing the transparent encapsulant into solid-form to form an optical coupling layer;
premixing an encapsulant in liquid-form having a wavelength-converting material;
dispensing the encapsulant into the at least one cavity to form an encapsulation layer;
allowing the wavelength-converting material to precipitate, forming thereon a high density layer and a low density layer within the encapsulation layer, wherein the high density layer comprises the wavelength-converting material precipitated on one side and the low density layer comprises the wavelength-converting material suspending in particle form;
curing the encapsulation layer into solid form;
removing the casting member; and
isolating each individual light-emitting device.

12. The method of claim 11, further comprising removing any curvature portion of the encapsulation layer to obtain a substantially flat encapsulation layer.

13. The method of claim 11, wherein the method further comprises rotating the casting member during the step of allowing the wavelength-converting material to precipitate.

14. The method of claim 11, wherein the step of isolating each individual light source device comprises sawing the substrate.

15. The method of claim 11, wherein the casting member comprises a plurality of cavities and the light source dies in each cavity are cast simultaneously.

16. A light source package, comprising:
a plurality of conductors;
at least one light source die attached on one of the conductors;
a wavelength converting layer;
an optical coupling layer separating the at least one light source die from the wavelength converting layer;
wherein the wavelength converting layer further comprises a low density layer having wavelength converting particles suspended within the layer; and
wherein the wavelength converting layer further comprises a high density layer connected to the low density layer having precipitated wavelength converting particles.

17. The light source package of claim 16, wherein the high density layer further comprises at least one side surface that defines a portion of side surfaces of the light source package.

18. The light source package of claim 16, wherein the wavelength converting layer comprises a top flat surface defining top surface of the light source package.

19. A flash system for use in a mobile device, comprising:
a light source configured to emit light;
a wavelength converting layer;
a transparent separation layer encapsulating the light source and configured to distance the light source away from the wavelength converting layer; and
a controller circuit adapted for arrangement within the mobile device and electrically coupled with the light source for activating the light source to flash the light;
wherein the wavelength converting layer further comprises a low density layer having wavelength converting particles suspended within the layer;
wherein the wavelength converting layer further comprises a high density layer connected to the low density layer and having precipitated wavelength converting particles; and
wherein the light emitted from the light source has a narrow spectrum, and the light source is coupled with the wavelength converting layer through the transparent separation layer for converting the narrow spectrum light to broad spectrum light.

20. The flash system of claim 19 wherein the mobile device comprises a camera.
